(19) United States
(12) Patent Application Publication
(10) Pub. No.: US 2026/0215294 A1
(43) Pub. Date: Jul. 23, 2026

(54) SEMICONDUCTOR PACKAGE HAVING A DIE PAD, A SEMICONDUCTOR TRANSISTOR DIE AND A LAYER STRUCTURE HAVING A CERAMIC LAYER

(71) Applicant: Infineon Technologies Austria AG, Villach (AT)

(72) Inventors: Edward Fürgut, Dasing (DE); Thai Kee Gan, Melaka Tengah (MY); Robert Rõsner, Oberschleißheim (DE)

(21) Appl. No.: 19/177,761

(22) Filed: Apr. 14, 2025

(30) Foreign Application Priority Data
Apr. 25, 2024 (MY) PI2024002423
Jul. 26, 2024 (DE) 102024207069.6

(51) Int. Cl. H10W 70/40; H10W 70/04; H10W 72/00; H10W 90/00

(52) U.S. Cl. CPC H10W 70/481; H10W 70/047; H10W 70/411; H10W 70/479; H10W 72/07336; H10W 90/757; H10W 90/767

(57) ABSTRACT

A semiconductor package includes a leadframe having a die pad and a plurality of leads. The die pad has a first main face and a second main face opposite to the first main face. A semiconductor transistor die is disposed on the first main face of the die pad. A layer structure is disposed on the second main face of the die pad. The layer structure includes a ceramic layer. An encapsulant embeds the die pad, inner portions of the leads, the semiconductor transistor die, and the layer structure. At least a portion of an uppermost layer of the layer structure is exposed to the outside.

### TECHNICAL FIELD

The present disclosure relates to a semiconductor package and a method for fabricating the same.

### BACKGROUND

Packages may be denoted as usually encapsulated electronic components with electrical connects extending out of the encapsulant. For example, packages may be connected to an electronic periphery, for instance mounted on a printed circuit board and/or connected with a heat sink, and may be connected via connectors to a larger system.

Power density is an important driver for the industry. Related with this are performance, dimensions and reliability. The different packaging solutions are manifold and have to address the needs of a specific application.

In particular packages with power semiconductor chips may generate a considerable amount of heat during operation. This may limit reliability and performance. Efficiently removing heat from the package may be accomplished by a heat sink or the like. At the same time, electric reliability of a package is required.

For these and other reasons there is a need for the present disclosure.

### SUMMARY

A first aspect of the present disclosure is related to a semiconductor package comprising a leadframe comprising a die pad and a plurality of leads, the die pad comprising a first main face and a second main face opposite to the first main face, a semiconductor transistor die disposed on the first main face of the die pad, a layer structure disposed on the second main face of the die pad, the layer structure comprising a ceramic layer, and an encapsulant embedding the die pad, inner portions of the leads, the semiconductor transistor die, and the layer structure, wherein at least a portion of an uppermost layer of the layer structure is exposed to the outside.

A second aspect of the present disclosure is related to a method of manufacturing a semiconductor package, the method comprising providing a leadframe comprising a die pad and a plurality of leads, the die pad comprising a first main face and a second main face opposite to the first main face; attaching a semiconductor transistor die to the first main face of the die pad, attaching a layer structure the second main face of the die pad, the layer structure comprising one of a direct copper bond, a direct aluminium bond, an active metal braze, or an insulated metal substrate, and applying an encapsulant to embed the die pad, inner portions of the leads, the semiconductor transistor die, and the layer structure, so that at least a portion of an uppermost layer of the layer structure is exposed to the outside.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A to 1E show a perspective view on a leadframe (FIG. 1A), perspective views after attaching the layer structure (FIGS. 1B, FIG. 1C) and perspective views after applying the encapsulant (FIGS. 1D, FIG. 1E).

FIGS. 2A and 2B show top views on exemplary semiconductor packages, one with a metallic exposed top surface (FIG. 2A) and another one with a ceramic top surface (FIG. 2B).

FIGS. 3A and 3B show cross-sectional side views of exemplary semiconductor packages comprising gullwing leads.

FIGS. 4A to 4D show cross-sectional representations for illustrating an exemplary method for fabricating a semiconductor package.

### DETAILED DESCRIPTION

The embodiments described herein are provided as follows.

According to an embodiment of the semiconductor package of the first aspect, the layer structure comprises a ceramic layer and a first metallic layer disposed on a first main surface of the ceramic layer which first main surface is facing the die pad.

The layer structure can in particular be provided by a direct copper bond (DCB), an active metal braze (AMB) or an insulated metal substrate (IMS). In the case of a DCB in particular, the ceramic layer is normally covered on both of its main surfaces with a metallic layer, in particular a Cu layer. However, it is also possible for the ceramic layer to be covered with a metallic layer on only one of its main surfaces, namely on the main surface facing the pad. In this case, the ceramic layer forms the uppermost layer of the layer structure, which is at least partially exposed to the outside.

According to an embodiment of the semiconductor package of the first aspect, the leadframe is a dual gauge leadframe. In particular, only the die pad of the leadframe may comprise a thickened portion of the leadframe and therefore functions as an efficient heat spreader. The thickness of the die pad can be in a range from 0.5 mm to 2 mm.

On the customer´s side a heat sink can be applied to the top of the package and thus to the exposed uppermost layer of the layer structure. It can be expected that application voltages of 2 kV or even 3.3 kV will be possible due to the efficient heat dissipation.

According to an embodiment of the semiconductor package of the first aspect, at least part of the leads comprise a stepped structure. In particular, part of the leads may comprise two steps as will be shown in more detail later.

According to an embodiment of the semiconductor package of the first aspect, at least part of the leads are deformable or retractable.

According to an embodiment of the semiconductor package of the first aspect, the semiconductor package is a surface mount device.

According to an embodiment of the semiconductor package of the first aspect, the semiconductor package is designed for topside cooling.

The method according to the second aspect is not limited to the sequence of method specified above. In particular, it may be provided that the layer structure is applied first on the die pad and thereafter the semiconductor die.

According to an embodiment of the method of the second aspect, attaching the semiconductor transistor die to the first main face of the die pad is performed by soldering, in particular diffusion soldering, or sintering.

According to an embodiment of the method of the second aspect, attaching the layer structure to the die pad is performed by soldering, sintering or gluing.

According to an embodiment of the method of the second aspect, the method further comprises connecting part of the leads to the semiconductor transistor die by Cu-Cu-wire bonding or clip bonding.

In the following detailed description, reference is made to the accompanying drawings, which form a part hereof, and in which is shown by way of illustration specific embodiments in which the disclosure may be practiced. In this regard, directional terminology, such as "top", "bottom", "front", "back", etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms "bonded", "attached", "connected", "coupled" and/or "electrically connected/electrically coupled" are not meant to mean that the elements or layers must directly be contacted together; intervening elements or layers may be provided between the "bonded", "attached", "connected", "coupled" and/or "electrically connected/electrically coupled" elements, respectively. However, in accordance with the disclosure, the above-mentioned terms may, optionally, also have the specific meaning that the elements or layers are directly contacted together, i.e. that no intervening elements or layers are provided between the "bonded", "attached", "connected", "coupled" and/or "electrically connected/electrically coupled" elements, respectively.

Further, the word "over" used with regard to a part, element or material layer formed or located "over" a surface may be used herein to mean that the part, element or material layer be located (e.g. placed, formed, deposited, etc.) "indirectly on" the implied surface with one or more additional parts, elements or layers being arranged between the implied surface and the part, element or material layer. However, the word "over" used with regard to a part, element or material layer formed or located "over" a surface may, optionally, also have the specific meaning that the part, element or material layer be located (e.g. placed, formed, deposited, etc.) "directly on", e.g. in direct contact with, the implied surface.

The examples of a semiconductor device module may use various types of transistor devices. The examples may also use horizontal or vertical transistor devices wherein those structures may be provided in a form in which all contact elements of the transistor device are provided on one of the main faces of the semiconductor die (horizontal transistor structures) or in a form in which at least one electrical contact element is arranged on a first main face of the semiconductor die and at least one other electrical contact element is arranged on a second main face opposite to the main face of the semiconductor die (vertical transistor structures) like, for example, MOS transistor structures or IGBT (Insulated Gate Bipolar Transistor) structures. According to an embodiment, the semiconductor die comprises one or more of a vertical semiconductor transistor die, a semiconductor power transistor die, an IGBT die, a MOSFET die, a JFET die, a CoolMOS die, a wide band gap semiconductor transistor die, a SiC transistor die, or a GaN transistor die.

According to an embodiment of the semiconductor package, the semiconductor transistor die is a semiconductor power transistor die. Here, the term "power semiconductor transistor die" may refer to a semiconductor die providing at least one of high voltage blocking or high current-carrying capabilities. A power semiconductor die may be configured for high currents having a maximum current value of a few Amperes, such as e.g. 10 A, 250 A, 600 A, 1000 A, or a maximum current value of up to or even exceeding 1000 A. Similarly, voltages associated with such current values may have values of a few Volts to a few tens or hundreds or even thousands of Volts.

The examples of a semiconductor package may comprise an encapsulant or encapsulating material having the semiconductor transistor die and the semiconductor driver die embedded therein. The encapsulating material can be any electrically insulating material like, for example, any kind of molding material, any kind of resin material, or any kind of epoxy material. The encapsulating material can also be a polymer material, a polyimide material, a thermoplast material, a silicone material, a ceramic material, and a glass material. The encapsulating material may also comprise any of the above-mentioned materials and further include filler materials embedded therein like, for example, thermally conductive increments like thermally conductive particles like, for example, made of AlO, BNi, AlNi, SiN, diamond, any other thermally conductive particles, or non-thermal conductive fillers, e.g. SiO, SiO2, glass etc.

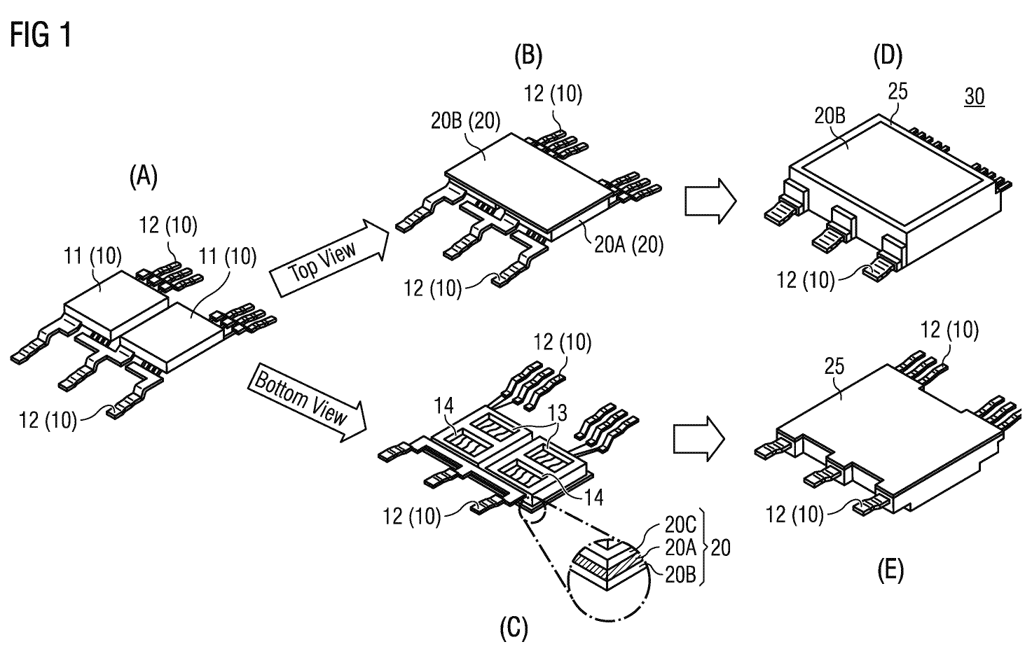

FIGS. 1A to 1E show a perspective view on a leadframe (FIG. 1A), perspective views after attaching the layer structure (FIGS. 1B, FIG. 1C) and perspective views after applying the encapsulant (FIGS. 1D, FIG. 1E).

More specifically, FIG. 1A shows a leadframe 10 comprising two die pads 11 and a plurality of leads 12, the two die pads 11 each comprising a first main face and a second main face opposite to the first main face. Two semiconductor dies (not shown in FIG. 1A, cf. FIG. 1C) are disposed on the respective back surfaces of the die pads, one of them being a semiconductor transistor die 13 and the other one being a semiconductor diode die 14 connected in parallel to the semiconductor transistor die.

FIGS. 1B and 1C show a layer structure 20 disposed on the front surfaces of the die pads 11. In the present embodiment the layer structure 20 comprises a direct copper bond (DCB) 20 comprising a center ceramic layer 20A, a first Cu layer 20B on an upper surface of the ceramic layer 20A, and a second Cu layer 20C on a lower surface of the ceramic layer 20A (see the enlarged section in the circle in FIG. 1C). The ceramic layer can, for example, be made of Al2O3, AlN, or Si3N4. The DCB 20 is connected with its second Cu layer 20C to the upper surfaces of the two die pads 11. There may be a solder layer, a sintered layer, or an adhesive layer in between. FIG. 1C also shows the bond wires connected between the pins 12 and contact pads of the semiconductor dies 13 and 14 and connected between the semiconductor transistor die 13 and the semiconductor diode die 14.

FIGS. 1D and 1E show the fabricated semiconductor package 30 after applying an encapsulant 25 embedding the die pads 11, inner portions of the leads 12, the semiconductor dies 13 and 14, and the DCB 20, wherein a major portion of the first Cu layer 20B of the DCB 20 is exposed to the outside. A customer can apply a heatsink onto the upper surface of the semiconductor package 30 and the first Cu layer 20B of the DCB 20.

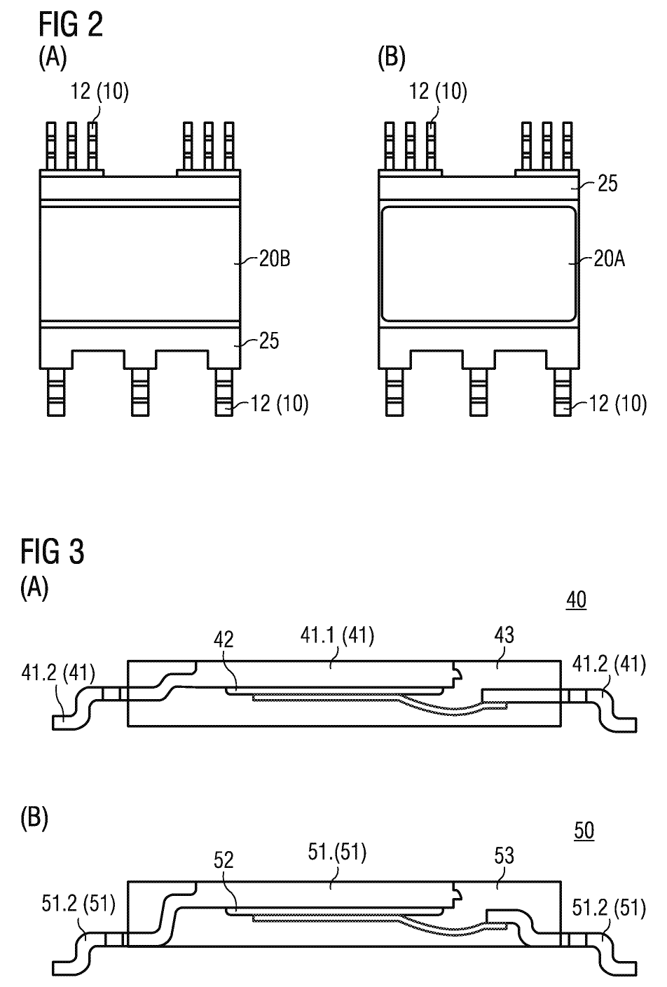

FIGS. 2A and 2B show top views on exemplary semiconductor packages, one with a metallic exposed top surface (FIG. 2A) and another one with a ceramic top surface (FIG. 2B).

More specifically, FIG. 2A shows an embodiment such as that of FIGS. 1A-1E in which the uppermost layer is conductive, in particular the first Cu layer 20B of the PCB. It may also comprise another electrically conductive material such as Al, Ag, Ni, etc.

In contrast to the above embodiment of FIGS. 2A, FIG. 2B shows an embodiment in which the uppermost layer of the layer structure is a ceramic layer. This is the case, for example, with a modified DCB that has a Cu layer only on one of its main surfaces. In this case, this would be the main surface of the DCB facing the die pad. In contrast to FIG. 2A, no Cu layer is applied to the upper surface of the ceramic layer of the DCB, so that the ceramic layer is exposed at the top after encapsulation. The material of the ceramic layer can be Al2O3, AlN or Si3N4, for example.

FIGS. 3A and 3B show cross-sectional side views of exemplary semiconductor packages comprising gullwing leads.

FIG. 3A shows an embodiment of s semiconductor package 40 comprising a leadframe 41 comprising a die pad 41.1 and a plurality of leads 41.2, a semiconductor transistor die 42 attached to the die pad 41.1, and an encapsulant 43. The leads on the left-hand side are connected with the die pad 41.1 and comprise a two-step structure. The leads on the right-hand side are connected by bond wires to the semiconductor die 42. Lower ends of the leads 41.2 are coplanar with a lowermost main surface of the encapsulant 43.

FIG. 3B shows an embodiment of s semiconductor package 50 comprising a leadframe 51 comprising a die pad 51.1 and a plurality of leads 51.2, a semiconductor transistor die 52 attached to the die pad 51.1, and an encapsulant 53. The leads on the left-hand side are connected with the die pad 51.1 and comprise a two-step structure. The leads on the right-hand side are connected by bond wires to the semiconductor die 52 and also comprise a two-step structure. Lower ends of the leads 51.2 are located in a plane below a lowermost main surface of the encapsulant 53.

The leads of both semiconductor packages 40 and 50 have gullwings outside the encapsulant. This has a positive effect on clearance and the avoidance of leakage currents. Another effect of the gullwings is an improvement in automation and second-level reliability.

With the aid of the two stages and the gullwing shape of the leads in the semiconductor package 50, it is possible to construct this semiconductor package in the same way as a leadless package, i.e. at least one horizontal section of the leads is flush with the underside of the package. This increases the clearance distance to any heat sink connected to the top side.

There is a further advantage with semiconductor packages in which the ceramic layer on the top of the package is exposed to the outside. This is because in this case there are no longer any conductive surfaces between the voltage domains, which means that the clearance distance or the creepage distance is equal to the distance between the voltage domains along the top of the package.

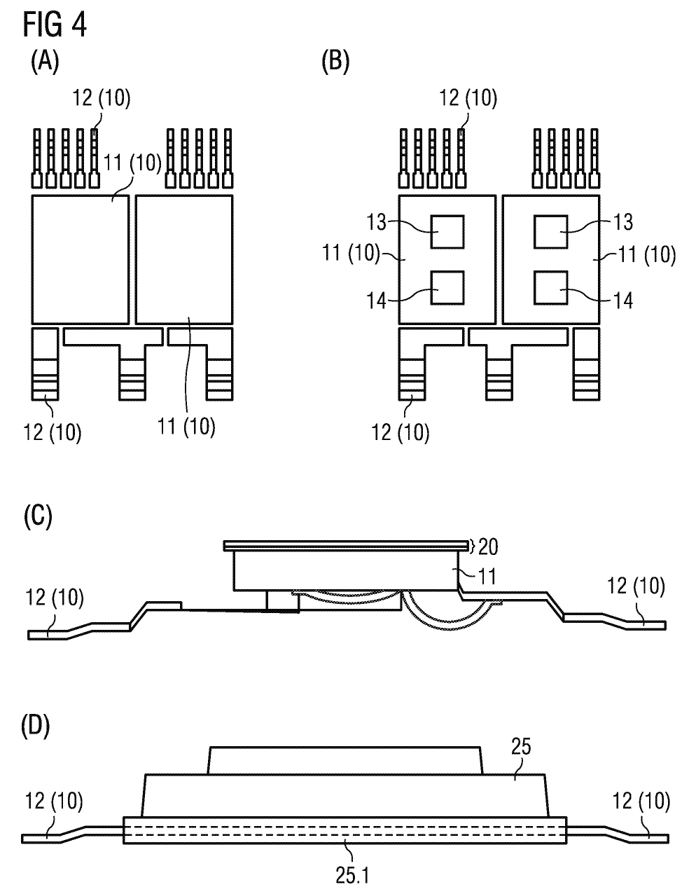

FIGS. 4A to 4D show cross-sectional representations for illustrating an exemplary method for fabricating a semiconductor package.

FIG. 4A shows the providing of a leadframe 10 comprising two die pads 11 and a plurality of leads 12, the die pads 11 each comprising a first main face and a second main face opposite to the first main face. The leadframe 10 can be a dual gauge leadframe comprising a thickened portion in the area of the die pad. The leadframe 10 may comprise copper or a copper alloy and may comprise a Ni or NiP coating.

FIG. 4B shows attaching a semiconductor transistor die 13 and a semiconductor diode die 14 to the first main faces of each one of the die pads 11. Attaching the semiconductor dies, for example, be performed by diffusion soldering.

FIG. 4C shows attaching a layer structure 20 to the second main faces of the die pads 11, the layer structure 20 comprising one of a direct copper bond, a direct aluminum bond, an active metal braze, or an insulated metal substrate. Attaching the layer structure can, for example, be performed by applying a preform soft solder layer onto one or both of the layer structure and the die pad, and melting and subsequently solidifying the soft solder layer.

Before or after attaching the layer structure 20 to the die pads 11, the leads 12 can be connected by bond wires to the semiconductor dies 13 and 14. The bond wires can be made of copper or aluminum.

FIG. 4D shows applying an encapsulant to embed the die pads 11, inner portions of the leads 12, the semiconductor dies 13 and 14, and the layer structure 20, so that at least a portion of an uppermost layer of the layer structure 20 is exposed to the outside. Applying the encapsulant can, for example, be done by either one of transfer molding, compression molding, or injection molding. As can further be seen, the encapsulant 25 may comprise a lowermost portion 25.1 which is laterally widened compared to the other portions of the encapsulant 15 and surrounds the inner portions of the leads 12.

It should be added that the semiconductor package may comprise either a single semiconductor transistor die (monoswitch) or as shown in the above embodiments two or more semiconductor transistor dies which may be interconnected to form, for example, a half-bridge, a full-bridge circuit, or boost (switch and diodes) or diode configurations.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms "include", "have", "with", or other variants thereof are used in either the detailed description or the claims, such terms are intended to be inclusive in a manner similar to the term "comprise". Furthermore, it should be understood that embodiments of the disclosure may be implemented in discrete circuits, partially integrated circuits or fully integrated circuits or programming means. Also, the term "exemplary" is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor package, comprising:
a leadframe comprising a die pad and a plurality of leads, the die pad comprising a first main face and a second main face opposite to the first main face;
a semiconductor transistor die on the first main face of the die pad;
a layer structure on the second main face of the die pad, the layer structure comprising a ceramic layer; and
an encapsulant embedding the die pad, inner portions of the leads, the semiconductor transistor die, and the layer structure,
wherein at least a portion of an uppermost layer of the layer structure is exposed to the outside.

2. The semiconductor package of claim 1, wherein the layer structure comprises one of a direct copper bond, an active metal braze, or an insulated metal substrate.

3. The semiconductor package of claim 1, wherein the layer structure comprises a ceramic layer and a first metallic layer on a first main surface of the ceramic layer, the first main surface facing the die pad.

4. The semiconductor package of claim 3, wherein the layer structure comprises a second metallic layer on a second main surface of the ceramic layer, the second main surface being remote from the die pad.

5. The semiconductor package of claim 1, wherein the die pad comprises a thickened portion of the leadframe.

6. The semiconductor package of claim 5, wherein a thickness of the die pad is in a range from 0.5 mm to 2 mm.

7. The semiconductor package of claim 1, wherein at least part of the leads comprises a stepped structure.

8. The semiconductor package of claim 7, wherein at least part of the leads comprise two steps from a lower mounting level to a level of the die pad.

9. The semiconductor package of claim 1, wherein the leads comprise external ends located in a plane below a lowermost surface of the encapsulant.

10. The semiconductor package of claim 1, wherein at least part of the leads are deformable or retractable.

11. The semiconductor package of claim 1, wherein the encapsulant has a lowermost portion which is laterally widened compared to other portions of the encapsulant and surrounds the inner portions of the leads.

12. The semiconductor package of claim 1, wherein the semiconductor transistor die comprises one or more of a vertical semiconductor transistor die, a semiconductor power transistor die, an IGBT die, a MOSFET die, a JFET die, a CoolMOS die, a wide band gap semiconductor transistor die, a SiC transistor die, or a GaN transistor die.

13. The semiconductor package of claim 1, further comprising:
a semiconductor diode die.

14. The semiconductor package of claim 1, wherein the semiconductor package is a surface mount device.

15. A method of manufacturing a semiconductor package, the method comprising:
providing a leadframe comprising a die pad and a plurality of leads, the die pad comprising a first main face and a second main face opposite to the first main face;
attaching a semiconductor transistor die to the first main face of the die pad;
attaching a layer structure to the second main face of the die pad, the layer structure comprising one of a direct copper bond, a direct aluminum bond, an active metal braze, or an insulated metal substrate; and
applying an encapsulant to embed the die pad, inner portions of the leads, the semiconductor transistor die, and the layer structure, so that at least a portion of an uppermost layer of the layer structure is exposed to the outside.

16. The method of claim 15, wherein attaching the semiconductor transistor die to the first main face of the die pad comprises:
soldering, diffusion soldering, or sintering the semiconductor transistor die to the first main face of the die pad.

17. The method of claim 15, wherein attaching the layer structure to the second main face of the die pad comprises:
soldering, sintering or gluing the layer structure to the second main face of the die pad.

18. The method of claim 15, further comprising:
connecting part of the leads to the semiconductor transistor die by Cu-Cu-wire bonding or clip bonding.
